(19) United States
(12) Patent Application Publication
(10) Pub. No.: US 2025/0228073 A1
(43) Pub. Date: Jul. 10, 2025

(54) DISPLAY DEVICE

(71) Applicant: Sharp Display Technology Corporation, Kameyama City, Mie (JP)

(72) Inventors: Takao SAITOH, Kameyama City, Mie (JP); Yohsuke KANZAKI, Kameyama City, Mie (JP); Masaki YAMANAKA, Kameyama City, Mie (JP); Masahiko MIWA, Kameyama City, Mie (JP); Yi SUN, Kameyama City, Mie (JP); Masaki FUJIWARA, Kameyama City, Mie (JP); Kouhei KAMATANI, Kameyama City, Mie (JP)

(21) Appl. No.: 18/850,776

(22) PCT Filed: May 13, 2022
(86) PCT No.: PCT/JP2022/020213

§ 371 Date: Sep. 25, 2024

(51) Int. Cl. H10K 59/121; H10D 86/40; H10D 86/60; H10K 59/126

(52) U.S. Cl. CPC H10K 59/1213; H10K 59/126; H10D 86/421; H10D 86/441; H10D 86/60

(57) ABSTRACT

A display device includes: a resin substrate; and a TFT layer provided on the resin substrate, and including a plurality of TFTs arranged for each of subpixels forming a display region. Each of the TFTs has a semiconductor layer formed of a polysilicon film. The plurality of TFTs are electrically connected to one another through a conductor region of the semiconductor layer. The TFT layer includes a light-shielding film provided to the semiconductor layer toward the resin substrate. The light-shielding film has a peripheral end disposed outside a peripheral end of the semiconductor layer.

### TECHNICAL FIELD

The disclosure relates to a display device.

### BACKGROUND ART

In recent years, light-emitting organic electroluminescence (EL) display devices using organic EL elements have attracted attention as a replacement for liquid crystal display devices. These organic EL display devices include flexible organic EL display devices. A proposed flexible display device has organic EL elements formed on a flexible resin substrate.

For example, Patent Document 1 discloses a thin-film transistor array substrate in which a lower light-shielding film is provided to a polycrystalline silicon film toward a light-transparent substrate.

### CITATION LIST

### Patent Literature

[Patent Document 1] Japanese Unexamined Patent Application Publication No. 2005-241910

### SUMMARY

### Technical Problem

In a flexible organic EL display device, a light-shielding film would be provided to a semiconductor layer, including thin-film transistors (TFTs), toward a resin substrate, so that polarization of the resin substrate does not affect characteristics of the TFTs. Here, a minimum unit of an image is a subpixel, and the subpixel is provided with a plurality of TFTs. When, for example, the plurality of TFTs are electrically connected together through a conductor region (doped with impurity ions) of the semiconductor layer formed of a polysilicon film, if the light-shielding film is provided to the semiconductor layer toward the resin substrate, a level difference (on a peripheral end) of the light-shielding film might break the semiconductor layer. Such a configuration has room for improvement.

The disclosure is conceived in view of the above problem, and sets out to reduce the risk that a semiconductor layer is broken because of a level difference of a light-shielding film provided to the semiconductor layer toward a resin substrate.

### Solution to Problem

In order to achieve the above object, a display device according to the disclosure includes: a resin substrate; and a thin-film transistor layer provided on the resin substrate, and including a plurality of thin-film transistors arranged for each of a plurality of subpixels forming a display region. Each of the thin-film transistors has a semiconductor layer formed of a polysilicon film. The plurality of thin-film transistors are electrically connected to one another through a conductor region of the semiconductor layer. The thin-film transistor layer includes a light-shielding film provided to the semiconductor layer toward the resin substrate. The light-shielding film has a peripheral end disposed outside a peripheral end of the semiconductor layer including the conductor region.

### ADVANTAGEOUS EFFECT OF DISCLOSURE

The disclosure can reduce the risk that a semiconductor layer is broken because of a level difference of a light-shielding film provided to the semiconductor layer toward a resin substrate.

### BRIEF DESCRIPTION OF DRAWINGS

FIG. 1 is a plan view of a schematic configuration of an organic EL display device according to a first embodiment of the disclosure.

FIG. 2 is a plan view of a display region of a TFT layer included in the organic EL display device according to the first embodiment of the disclosure.

FIG. 3 is an equivalent circuit diagram of the TFT layer included in the organic EL display device according to the first embodiment of the disclosure.

FIG. 4 is a cross-sectional view of the TFT layer and the organic EL display device including the TFT layer, taken along line IV-IV in FIG. 2.

FIG. 5 is a plan view of an arrangement of a light-shielding film and a semiconductor layer included in the TFT layer of the organic EL display device according to the first embodiment of the disclosure.

FIG. 6 is a cross-sectional view of an organic EL layer included in the organic EL display device according to the first embodiment of the disclosure.

FIG. 7 is a plan view of an arrangement of a light-shielding film and a semiconductor layer included in a TFT layer of an organic EL display device according to a second embodiment of the disclosure. FIG. 7 corresponds to FIG. 5.

FIG. 8 is a plan view of an arrangement of a light-shielding film and a semiconductor layer included in a TFT layer of an organic EL display device according to a third embodiment of the disclosure. FIG. 8 corresponds to FIG. 5.

### DESCRIPTION OF EMBODIMENTS

Embodiments of the disclosure will be described in detail below with reference to the drawings. Note that the disclosure shall not be limited to the embodiments below.

### First Embodiment

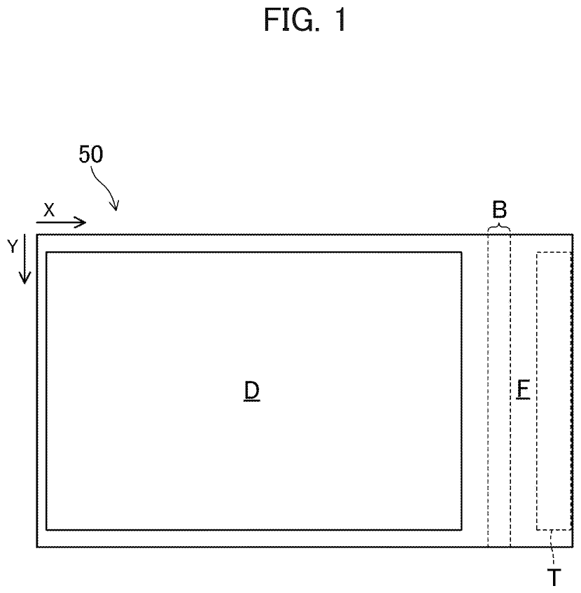

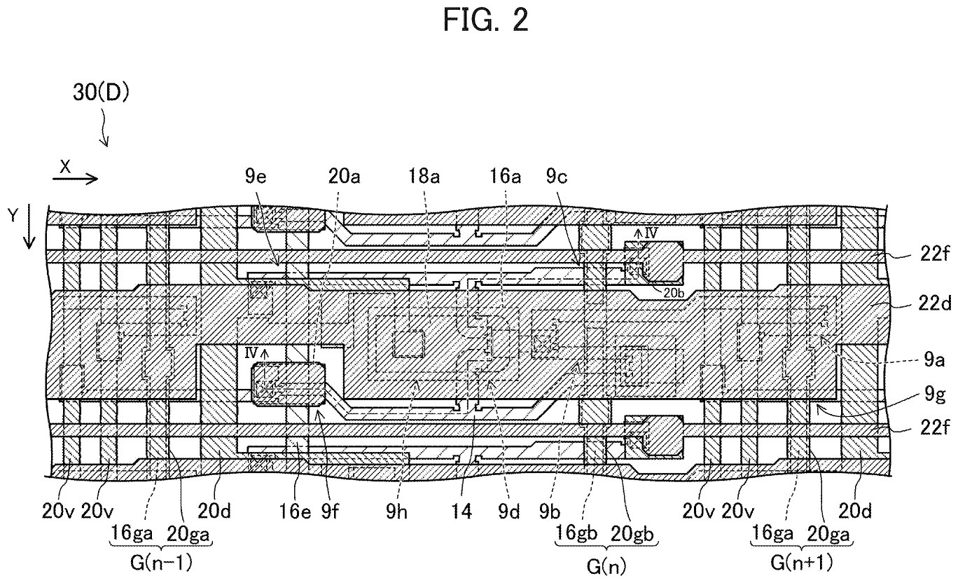

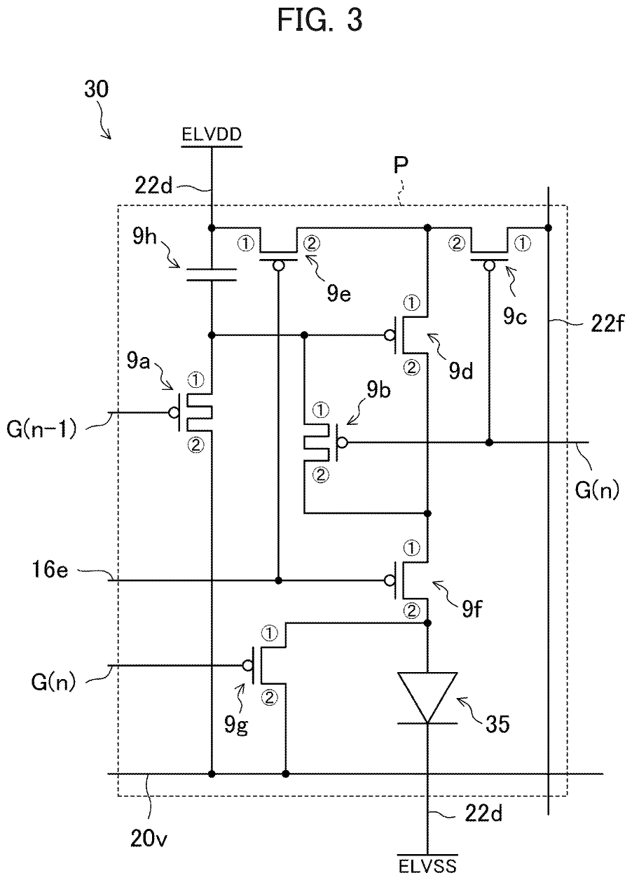

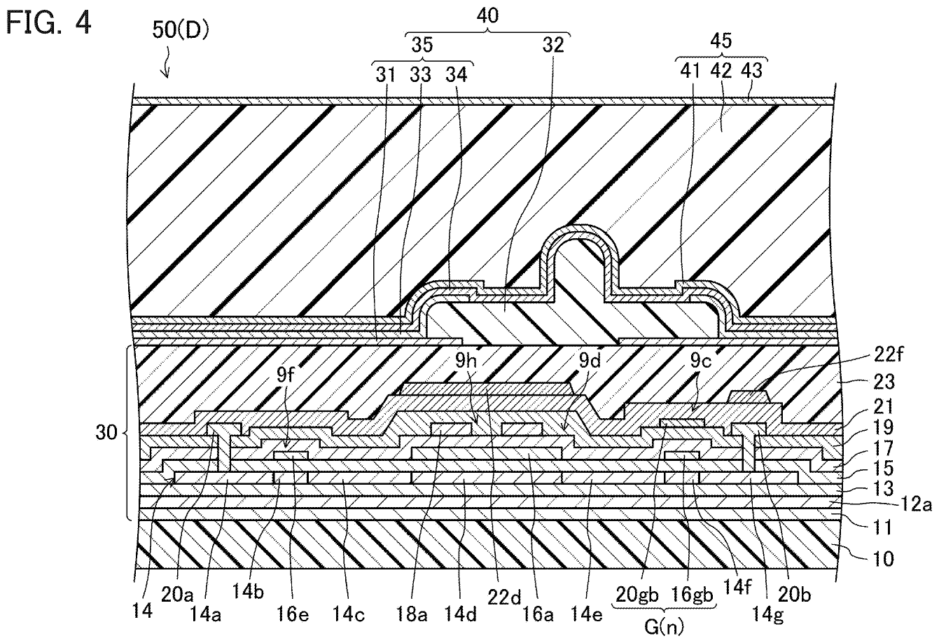

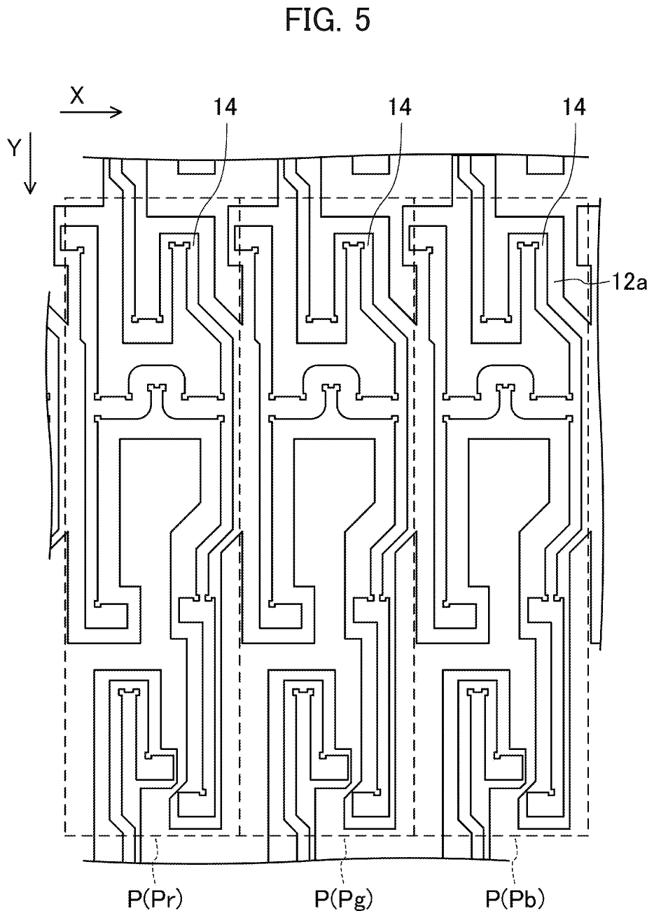

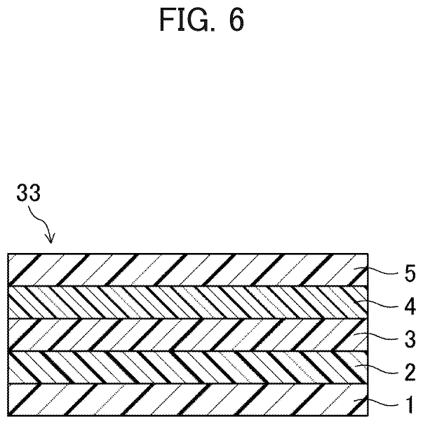

FIGS. 1 to 6 illustrate a first embodiment of a display device according to the disclosure. Note that, in the embodiments below, an organic EL display device including an organic EL element layer is exemplified as a display device including a light-emitting-element layer. Here, FIG. 1 is a plan view of a schematic configuration of an organic EL display device 50 according to this embodiment. FIG. 2 is a plan view of a principal configuration of a display region D of a TFT layer 30 included in the organic EL display device 50. FIG. 3 is an equivalent circuit diagram of the TFT layer 30 included in the organic EL display device 50. FIG. 4 is a cross-sectional view of the TFT layer 30 and the organic EL display device 50 including the TFT layer 30, taken along line IV-IV in FIG. 2. FIG. 5 is a plan view of an arrangement of a light-shielding film 12a and a semiconductor layer 14 included in the TFT layer 30 of the organic EL display device 50. FIG. 6 is a cross-sectional view of an organic EL layer 33 included in the organic EL display device 50.

As illustrated in FIG. 1, the organic EL display device 50 includes, for example: the display region D shaped into a rectangle and displaying an image; and a picture-frame region F provided around the display region D. Note that this embodiment exemplifies the display region D shaped into a rectangle. Examples of the rectangle include such substantial rectangles as a rectangle having arc-like sides, a rectangle having rounded corners, and a rectangle having partially notched sides.

The display region D includes a plurality of subpixels P (see FIG. 5) arranged in a matrix. Moreover, in the display region D, as illustrated in FIG. 5, for example, subpixels Pr for presenting red, subpixels Pg for presenting green, and subpixels Pb presenting blue are provided side by side. Note that, in the display region D, for example, neighboring three subpixels Pr, Pg, and Pb constitute one pixel.

The picture-frame region F in FIG. 1 has an end portion in the positive X-direction. The end portion is provided with a terminal unit T extending in one direction (in a Y-direction in FIG. 1). Moreover, as illustrated in FIG. 1, the picture-frame region F includes, for example, a folding portion B between the display region D and the terminal unit T. The folding portion B, extending in one direction (in the Y-direction in the drawing), is foldable around a folding axis in the Y-direction in the drawing at an angle of 180° (foldable in a U-shape).

As illustrated in FIG. 4, the organic EL display device 50 includes: a resin substrate 10; the TFT layer 30 provided on the resin substrate 10; an organic-EL-element layer 40 provided on the TFT layer 30 and serving as a light-emitting-element layer; and a sealing film 45 provided on the organic-EL-element layer 40.

The resin substrate 10 is made of, for example, an organic resin material such as polyimide resin.

As illustrated in FIG. 4, the TFT layer 30 includes: a first base coat film 11 and a second base coat film 13 sequentially provided above the resin substrate 10; a first TFT 9a (see FIG. 3), a second TFT 9b (see FIG. 3), a third TFT 9c, a fourth TFT 9d, a fifth TFT 9e (see FIG. 3), a sixth TFT 9f, a seventh TFT 9g (see FIG. 3), and a capacitor 9h, all of which are provided on the second base coat film 13 for each of the subpixels P; and a protective insulating film 21 and a planarization film 23 sequentially provided above the TFTs 9a to 9g and the capacitor 9h. Furthermore, as illustrated in FIG. 4, the TFT layer 30 includes: the semiconductor layer 14; a gate insulating film 15; a first metal layer (e.g., a gate electrode 16a to be described later); a first interlayer insulating film 17; a second metal layer (e.g., a capacitive electrode 18a to be described later); a second interlayer insulating film 19; and a third metal layer (e.g., an initialization power supply line 20v), all of which are provided between the second base coat film 13 and the protective insulating film 21, and stacked on top of another from the second base coat film 13 toward the protective insulating film 21. Here, the TFT layer 30 includes, as illustrated in FIG. 2, a plurality of gate lines G extending in parallel with one another in the Y-direction in the drawing. Note that, as illustrated in FIG. 2, one of a gate line G(n−1) or a gate line G(n+1) in a pair of gate lines G arranged side by side includes: a lower wiring layer 16ga of the first metal layer; and an upper wiring layer 20ga of the third metal layer. Another gate line in the pair; namely, a gate line G(n) includes: a lower wiring layer 16gb of the first metal layer; and an upper wiring layer 20gb of the third metal layer. The lower wiring layer 16ga and the upper wiring layer 20ga are electrically connected together through a contact hole formed in the first interlayer insulating film 17 and the second interlayer insulating film 19. The lower wiring layer 16gb and the upper wiring layer 20gb are electrically connected together through a contact hole formed in the first interlayer insulating film 17 and the second interlayer insulating film 19. Moreover, the TFT layer 30 includes, as illustrated in FIG. 2, a plurality of light-emission control lines 16e extending in parallel with one another in the Y-direction in the drawing. In addition, the TFT layer 30 includes, as illustrated in FIG. 2, a plurality of the initialization power supply lines 20v extending in parallel with one another in the Y-direction in the drawing. Furthermore, the TFT layer 30 includes, as illustrated in FIG. 2, a plurality of first power supply lines 20d extending in parallel with one another in the Y-direction in the drawing. Moreover, the TFT layer 30 includes, as illustrated in FIG. 2, a plurality of source lines 22f extending in parallel with one another in the X-direction in the drawing. In addition, the TFT layer 30 includes, as illustrated in FIG. 2, a plurality of second power supply lines 22d extending in parallel with one another in the X-direction in the drawing. Note that the second power supply lines 22d are electrically connected to the first power supply lines 20d through contact holes formed in the protective insulating film 21.

Each of the first base coat film 11, the second base coat film 13, the gate insulating film 15, the first interlayer insulating film 17, the second interlayer insulating film 19, and the protective insulating film 21 is an inorganic monolayer insulating film made of such a substance as, for example, silicon nitride, silicon oxide, or silicon oxynitride. Alternatively, each film is an inorganic multilayer insulating film made of these substances.

Each of the first TFT 9a to the seventh TFT 9g includes: the semiconductor layer 14 formed of a polysilicon film; a first terminal electrode (see circled reference numeral 1 in FIG. 3) and a second terminal electrode (see circled reference numeral 2 in FIG. 3) spaced apart from each other; and a gate electrode overlapping with a channel region of the semiconductor layer 14 so as to control conduction between the first terminal electrode and the second terminal electrode. The channel region will be described later. Note that the first terminal electrode and the second terminal electrode of each of the first TFT 9a to the seventh TFT 9g are a conductor region of the semiconductor layer 14 doped with impurity ions. Hence, in a pair of TFTs electrically connected together, either the first terminal electrode or the second terminal electrically of one of the TFTs is electrically connected to either the first terminal electrode or the second terminal electrode of another one of the TFTs through a conductor region of the common semiconductor layer 14.

The first TFT 9a serves as an initialization TFT. As illustrated in FIG. 3, in each subpixel P, the first TFT 9a has: a gate electrode electrically connected to the corresponding gate line G; the first terminal electrode electrically connected to the gate electrode 16a of the capacitor 9h to be described later; and the second terminal electrode electrically connected to the corresponding initialization power supply line 20v. Then, the first TFT 9a applies a voltage of the initialization power supply line 20v to the capacitor 9h so as to initialize a voltage to be applied to the gate electrode of the fourth TFT 9d. Note that, as illustrated in FIG. 3, the gate electrode of the first TFT 9a is electrically connected to the gate line G(n−1) to be scanned immediately before the gate line G(n) electrically connected to the gate electrode of each of the second TFT 9b, the third TFT 9c, and the seventh TFT 9g.

The second TFT 9b serves as a compensation TFT. As illustrated in FIG. 3, in each subpixel P, the second TFT 9b has: a gate electrode electrically connected to the corresponding gate line G; the first terminal electrode electrically connected to the gate electrode of the fourth TFT 9d; and the second terminal electrode electrically connected to the second terminal electrode of the fourth TFT 9d. Then, the second TFT 9b makes the fourth TFT 9d diode-connected when the gate line G is selected, so as to compensate for a threshold voltage of the fourth TFT 9d.

The third TFT 9c serves as a write TFT. As illustrated in FIG. 3, in each subpixel P, the third TFT 9c has: a gate electrode electrically connected to the corresponding gate line G; the first terminal electrode electrically connected to the corresponding source line 22f, and the second terminal electrode electrically connected to the first terminal electrode of the fourth TFT 9d. Then, the third TFT 9c applies a voltage of the source line 22f to the first terminal electrode of the fourth TFT 9d when the gate line G is selected. Furthermore, as illustrated in the cross-sectional view of the FIG. 4, the third TFT 9c includes: the semiconductor layer 14 provided on the second base coat film 13; and the lower wiring layer 16gb (of the gate line G) provided above the semiconductor layer 14 through the gate insulating film 15 and serving as a gate electrode. Here, as illustrated in FIG. 4, the semiconductor layer 14 includes: a channel region 14f overlapping with the lower wiring layer 16gb; and a conductor region 14e and a conductor region 14g spaced apart from each other across the channel region 14f, and respectively serving as the second terminal electrode and the first terminal electrode of the third TFT 9c. Note that, as illustrated in FIG. 4, the conductor region 14g is electrically connected to a relay electrode 20b through a contact hole formed in the gate insulating film 15, the first interlayer insulating film 17, and the second interlayer insulating film 19. The relay electrode 20b is electrically connected to the source line 22f through a contact hole (not shown) formed in the protective insulating film 21.

The fourth TFT 9d serves as a drive TFT. As illustrated in FIG. 3, in each subpixel P, the fourth TFT 9d has: the gate electrode 16a (see FIG. 4) electrically connected to the first terminal electrode of each of the first TFT 9a and the second TFT 9b; the first terminal electrode electrically connected to the second terminal electrode of each of the third TFT 9c and the fifth TFT 9e; and the second terminal electrode electrically connected to the second terminal electrode of the second TFT 9b and to the first terminal electrode of the sixth TFT 9f. Then, the fourth TFT 9d applies a drive current, based on a voltage to be applied between the gate electrode and the first terminal electrode of the fourth TFT 9d, to the first terminal electrode of the sixth TFT 9f. Furthermore, as illustrated in the cross-sectional view of the FIG. 4, the fourth TFT 9d includes: the semiconductor layer 14 provided on the second base coat film 13; and the gate electrode 16a provided above the semiconductor layer 14 through the gate insulating film 15. Here, as illustrated in FIG. 4, the semiconductor layer 14 includes: a channel region 14d overlapping with the gate electrode 16a; and a conductor region 14c and the conductor region 14e spaced apart from each other across the channel region 14d, and respectively serving as the second terminal electrode and the first terminal electrode of the fourth TFT 9d.

The fifth TFT 9e serves as a power supply TFT. As illustrated in FIG. 3, in each subpixel P, the fifth TFT 9e has: a gate electrode electrically connected to the corresponding light-emission control line 16e; the first terminal electrode electrically connected to the corresponding second power supply line 22d; and the second terminal electrode electrically connected to the first terminal electrode of the fourth TFT 9d. Then, the fifth TFT 9e applies a voltage of the second power supply line 22d to the first terminal electrode of the fourth TFT 9d when the light-emission control line 16e is selected.

The sixth TFT 9f serves as a light-emission control TFT. As illustrated in FIG. 3, in each subpixel P, the sixth TFT 9f has: a gate electrode electrically connected to the corresponding light-emission control line 16e; the first terminal electrode electrically connected to the second terminal electrode of the fourth TFT 9d; and the second terminal electrode electrically connected to a first electrode 31 of an organic EL element 35 to be described later. Then, the sixth TFT 9f applies the drive current to the organic EL element 35 when the light-emission control line 16e is selected. Furthermore, as illustrated in the cross-sectional view of the FIG. 4, the sixth TFT 9f includes: the semiconductor layer 14 provided on the second base coat film 13; and the light-emission control line 16e provided above the semiconductor layer 14 through the gate insulating film 15 and serving as a gate electrode. Here, as illustrated in FIG. 4, the semiconductor layer 14 includes: a channel region 14b overlapping with the light-emission control line 16e; and a conductor region 14a and the conductor region 14c spaced apart from each other across the channel region 14b, and respectively serving as the second terminal electrode and the first terminal electrode of the sixth TFT 9f. Note that, as illustrated in FIG. 4, the conductor region 14a is electrically connected to a relay electrode 20a through a contact hole formed in the gate insulating film 15, the first interlayer insulating film 17, and the second interlayer insulating film 19. The relay electrode 20a is electrically connected to the first electrode 31 through a contact hole (not shown) formed in the protective insulating film 21 and the planarization film 23.

The seventh TFT 9g serves as an anode discharge TFT. As illustrated in FIG. 4, in each subpixel P, the seventh TFT 9g has: a gate electrode electrically connected to the corresponding gate line G; the first terminal electrode electrically connected to the first electrode 31 of the organic EL element 35; and the second terminal electrode electrically connected to the corresponding initialization power supply line 20v. Then, the seventh TFT 9g resets charges accumulated in the first electrode 31 of the organic EL element 35 when the gate line G is selected.

In cross-section, similar to the third TFT 9c, each of the first TFT 9a, the second TFT 9b, the fifth TFT 9e, and the seventh TFT 9g includes: the semiconductor layer 14 provided on the second base coat film 13; and the gate electrode provided above the semiconductor layer 14 through the gate insulating film 15. Here, as illustrated in FIGS. 2 and 5, the semiconductor layer 14 bends and branches off in plan view, so as to be formed into a single piece among the first TFT 9a to the seventh TFT 9g. Furthermore, as illustrated in FIG. 5, the light-shielding film 12a is provided to the semiconductor layer 14 toward the resin substrate 10. The light-shielding film 12a reduces polarization caused when light enters the resin substrate 10, and reduces a shift of a threshold value for each of the first TFT 9a to the seventh TFT 9g.

The light-shielding film 12a is formed of a metal film such as, for example, a molybdenum film, a titanium film, or an aluminum film having a thickness of approximately 50 nm to 100 nm. The light-shielding film 12a is provided between the first base coat film 11 and the second basecoat film 13. Here, as illustrated in FIG. 5, the light-shielding film 12a has a peripheral end disposed outside a peripheral end of the semiconductor layer 14. Hence, the semiconductor layer 14 is not provided on a level difference created on a surface of the second base coat film 13 because of the peripheral end of the light-shielding film 12a. Furthermore, as illustrated in FIG. 5, the light-shielding film 12a is formed into a single piece among the plurality of subpixels P arranged side by side in the X-direction in the drawing.

As illustrated in FIG. 4, the capacitor 9h includes: the gate electrode 16a; the first interlayer insulating film 17 provided on the gate electrode 16a; and the capacitive electrode 18a provided on the first interlayer insulating film 17 so as to overlap with the gate electrode 16a. Furthermore, as illustrated in FIG. 3, the capacitor 9h in each subpixel P has the gate electrode 16a formed in conformity with, and thus electrically connected to, the gate electrode 16a of the fourth TFT 9d, and also electrically connected to the first terminal electrode of each of the first TFT 9a and the second TFT 9b. The capacitor 9h has the capacitive electrode 18a electrically connected to the corresponding second power supply line 22d through a contact hole (not shown) formed in the second interlayer insulating film 19 and the protective insulating film 21. Then, the capacitor 9h stores a voltage of the corresponding source line 22f when the corresponding gate line G is selected. The capacitor 9h holds the stored voltage to maintain a voltage applied to the gate electrode 16a of the fourth TFT 9d when the corresponding gate line G is not selected.

The planarization film 23 has a flat surface in the display region D. The planarization film 23 is made of such a material as, for example, an organic resin material such as polyimide resin or acrylic resin, or a polysiloxane-based spin-on-glass (SOG) material.

As illustrated in FIG. 4, the organic EL element layer 40 includes: a plurality of the organic EL elements 35 provided to serve as a plurality of light-emitting elements corresponding to the plurality of subpixels P and arranged in a matrix; and an edge cover 32 provided in a lattice form in common to all the subpixels P to cover a peripheral end portion of the first electrode 31 of each organic EL element 35.

As illustrated in FIG. 4, in each subpixel P, the organic EL element 35 includes: the first electrode 31 provided on the planarization film 23 of the TFT layer 30; an organic EL layer 33 provided on the first electrode 31; and a second electrode 34 provided on the organic EL layer 33.

The first electrode 31 is electrically connected to the second terminal electrode of the sixth TFT 9f for each subpixel P through: a contact hole (not shown) formed in the protective insulating film 21 and the planarization film 23; and the relay electrode 20a. Furthermore, the first electrode 31 has a function of injecting holes into the organic EL layer 33. Moreover, the first electrode 31 is preferably formed of a material having a large work function to improve efficiency in injecting the holes into the organic EL layer 33. Here, examples of the material forming the first electrode 31 include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Moreover, the first electrode 31 may be made of, for example, an alloy of astatine (At)/astatine oxide (AtO2). Moreover, the first electrode 31 may be made of a conductive oxide such as, for example, tin oxide (SnO), zinc oxide (ZnO), indium tin oxide (ITO), or indium zinc oxide (IZO). In addition, the first electrode 31 may be formed of a plurality of layers made of the above materials and stacked on top of another. Note that examples of compound materials having a large work function include indium tin oxide (ITO) and indium zinc oxide (IZO).

As illustrated in FIG. 6, the organic EL layer 33 includes: a hole injection layer 1; a hole transport layer 2; a light-emitting layer 3, an electron transport layer 4, and an electron injection layer 5, all of which are provided in the stated order above the first electrode 31.

The hole injection layer 1 is also referred to as an anode buffer layer. The hole injection layer 1 has a function of approximating energy levels between the first electrode 31 and the organic EL layer 33 to improve efficiency in injecting the holes from the first electrode 31 into the organic EL layer 33. Here, examples of a material forming the hole injection layer 1 include a triazole derivative, an oxadiazole derivative, an imidazole derivative, a polyarylalkane derivative, a pyrazoline derivative, a phenylenediamine derivative, an oxazole derivative, a styrylanthracene derivative, a fluorenone derivative, a hydrazone derivative, and a stilbene derivative.

The hole transport layer 2 has a function of improving efficiency in transporting the holes from the first electrode 31 to the organic EL layer 33. Here, examples of a material forming the hole transport layer 2 include a porphyrin derivative, an aromatic tertiary amine compound, a styrylamine derivative, polyvinyl carbazole, poly-p-phenylenevinylene, polysilane, a triazole derivative, an oxadiazole derivative, an imidazole derivative, a polyarylalkane derivative, a pyrazoline derivative, a pyrazolone derivative, a phenylenediamine derivative, an arylamine derivative, an amine-substituted chalcone derivative, an oxazole derivative, a styrylanthracene derivative, a fluorenone derivative, a hydrazone derivative, a stilbene derivative, hydrogenated amorphous silicon, hydrogenated amorphous silicon carbide, zinc sulfide, zinc selenide, and zinc selenide.

The light-emitting layer 3 is a region where the holes and the electrons are respectively injected from the first electrode 31 and the second electrode 34, and recombine together, when a voltage is applied with the first electrode 31 and the second electrode 34. Here, the light-emitting layer 3 is formed of a material having high light-emission efficiency. Examples of the material forming the light-emitting layer 3 include a metal oxinoid compound[8-hydroxyquinoline metal complex], a naphthalene derivative, an anthracene derivative, a diphenylethylene derivative, a vinylacetone derivative, a triphenylamine derivative, a butadiene derivative, a coumarin derivative, a benzoxazole derivative, an oxadiazole derivative, an oxazole derivative, a benzimidazole derivative, a thiadiazole derivative, a benzothiazole derivative, a styryl derivative, a styrylamine derivative, a bisstyrylbenzene derivative, a trisstyrylbenzene derivative, a perylene derivative, a perinone derivative, an aminopyrene derivative, a pyridine derivative, a rhodamine derivative, an aquizine derivative, phenoxazone, a quinacridone derivative, rubrene, poly-p-phenylenevinylene, and polysilane.

The electron transport layer 4 has a function of efficiently moving the electrons to the light-emitting layer 3. Here, examples of a material forming the electron transport layer 4 include, as organic compounds, an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, and a metal oxinoid compound.

The electron injection layer 5 has a function of approximating energy levels between the second electrode 34 and the organic EL layer 33 to improve efficiency in injecting the electrons from the second electrode 34 into the organic EL layer 33. Such a function can decrease a drive voltage of the organic EL element 35. Note that the electron injection layer 5 is also referred to as a cathode buffer layer. Here, examples of a material forming the electron injection layer 5 include: inorganic alkali compounds such as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

As illustrated in FIG. 4, the second electrode 34 is provided in common to all the subpixels P to cover each organic EL layer 33 and the edge cover 32. Moreover, the second electrode 34 has a function of injecting the electrons into the organic EL layer 33. Furthermore, the second electrode 34 is preferably formed of a material having a small work function to improve efficiency in injecting the electrons into the organic EL layer 33. Here, examples of the material forming the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Moreover, the second electrode 34 may be formed of an alloy such as magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), or lithium fluoride (LiF)/calcium (Ca)/aluminum (Al). Furthermore, the second electrode 34 may be formed of a conductive oxide such as tin oxide (SnO), zinc oxide (ZnO), indium tin oxide (ITO), or indium zinc oxide (IZO). In addition, the second electrode 34 may be formed of a plurality of layers made of the above materials and stacked on top of another. Note that examples of the material having a small work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

The edge cover 32 is made of, for example, an organic resin material such as polyimide resin or acrylic resin, or a polysiloxane-based SOG material.

As illustrated in FIG. 4, the sealing film 45 is provided to cover the second electrode 34, and includes: a first inorganic sealing film 41; an organic sealing film 42; and a second inorganic sealing film 43, all of which are stacked on top of another in the stated order above the second electrode 34. The sealing film 45 protects the organic EL layer 33 in the organic EL element layer 35 from moisture and oxygen.

Each of the first inorganic sealing film 41 and the second inorganic sealing film 43 is formed of such an inorganic insulating film as, for example, a silicon nitride film, a silicon oxide film, or a silicon oxynitride film.

The organic sealing film 42 is formed of such an organic resin material as, for example, acrylic resin, epoxy resin, silicone resin, polyurea resin, parylene resin, polyimide resin, or polyamide resin.

As to the organic EL display device 50 having the above configuration, in each subpixel P, when the light-emission control line 16e is first selected to be in an inactive state, the organic EL element 35 is in a non-light-emission state. In the non-light-emission state, the gate line G(n−1) in the preceding stage is selected. Through the gate line G(n−1), a gate signal is input into the first TFT 9a such that the first TFT 9a turns ON. Hence, the initialization signal of the corresponding initialization power supply line 20v is applied to the capacitor 9h, and the fourth TFT 9d turns ON. Thus, charges of the capacitor 9h are discharged, and a voltage to be applied to the gate electrode 16a of the fourth TFT 9d is initialized. Next, when the gate line G(n) of the corresponding stage is selected to be in the active state, the second TFT 9b and the third TFT 9c turn ON, and a predetermined voltage corresponding to a source signal to be transmitted through the corresponding source line 22f is written into the capacitor 9h through the diode-connected fourth TFT 9d. Simultaneously, the seventh TFT 9g turns ON, and an initialization signal is applied through the initialization power supply line 20v to the first electrode 31 of the organic EL element 35. Hence, the charges accumulated in the first electrode 31 are reset. After that, the light-emission control line 16e is selected, and the fifth TFT 9e and the sixth TFT 9f turn ON. Hence, a drive current corresponding to the voltage applied to the gate electrode 16a of the fourth TFT 9d is supplied from the second power supply line 22d to the organic EL element 35. Thus, in each subpixel P, the organic EL element 35 emits light the luminance of which corresponds to the drive current. This is how the organic EL display device 50 displays an image.

Described next will be a method for producing the organic EL display device 50 of this embodiment. Note that the method for producing the organic EL display device 50 includes: a TFT-layer forming step; an organic-EL-element-layer forming step; and a sealing-film forming step.

### TFT-Layer Forming Step

First, for example, an inorganic insulating film (approximately 500 nm in thickness) such as a silicon oxide film is deposed by plasma chemical vapor deposition (CVD) on the resin substrate 10 formed on a glass substrate. Hence, the first base coat film 11 is formed.

Then, on the entire substrate provided with the base coat film 11, a metal film such as a molybdenum film (approximately 75 nm in thickness) is deposited by, for example, sputtering. After that, the metal film is patterned to form the light-shielding film 12a.

After that, on the entire substrate provided with the light-shielding film 12a, an inorganic insulating film (approximately 500 nm in thickness) such as a silicon oxide film is deposited by, for example, the plasma CVD. Hence, the second base coat film 13 is formed.

Furthermore, on the entire substrate provided with the second base coat film 13, an amorphous silicon film (approximately 50 nm in thickness) is deposited by, for example, the plasma CVD. The amorphous silicon film is crystallized by such a technique as laser annealing to form a polysilicon film. The polysilicon film is patterned to form the semiconductor layer 14.

Then, on the entire substrate provided with the semiconductor layer 14, an inorganic insulating film (approximately 100 nm in thickness) such as a silicon oxide film is deposited by, for example, the plasma CVD. Hence, the gate insulating film 15 is formed.

After that, on the entire substrate provided with the gate insulating film 15, an aluminum film (approximately 350 nm in thickness) and a molybdenum nitride film (approximately 50 nm in thickness) are deposited in the stated order by, for example, sputtering. After that, the metal multilayer film including these films is patterned to form, for example, the gate electrode 16a.

Furthermore, using the gate electrode 16a as a mask, the semiconductor layer 14 is doped with impurity ions to have the channel regions 14b, 14d, and 14f and the conductor regions 14a, 14c, 14e, and 14g.

Then, on the entire substrate provided with the semiconductor layer 14 doped with impurity ions, an inorganic insulating film (approximately 100 nm in thickness) such as a silicon oxide film is deposited by, for example, the plasma CVD. Hence, the first interlayer insulating film 17 is formed.

After that, on the entire substrate provided with the first interlayer insulating film 17, an aluminum film (approximately 350 nm in thickness) and a molybdenum nitride film (approximately 50 nm in thickness) are deposited in the stated order by, for example, sputtering. After that, the metal multilayer film including these films is patterned to form, for example, the capacitive electrode 18a.

Furthermore, on the entire substrate provided with the capacitive electrode 18a, an inorganic insulating film (approximately 100 nm in thickness) such as a silicon oxide film is deposited by, for example, the plasma CVD. The inorganic insulating film and the other inorganic insulating film below are simultaneously patterned as appropriate so that a contact hole is formed. Hence, the second interlayer insulating film 19 is formed.

Then, on the entire substrate provided with the second interlayer insulating film 19, a titanium film (approximately 30 nm in thickness), an aluminum film (approximately 300 nm in thickness), and a titanium film (approximately 50 nm in thickness) are deposited in the stated order by, for example, sputtering. After that, the metal multilayer film including these films is patterned to form such layers as the first power supply line 20d.

After that, on the entire substrate provided with the first power supply line 20d, an inorganic insulating film (approximately 100 nm in thickness) such as a silicon oxide film is deposited by, for example, the plasma CVD. The inorganic insulating film is patterned as appropriate so that a contact hole is formed. Hence, the protective insulating film 21 is formed.

Furthermore, on the entire substrate provided with the protective insulating film 21, a titanium film (approximately 30 nm in thickness), an aluminum film (approximately 300 nm in thickness), and a titanium film (approximately 50 nm in thickness) are deposited in the stated order by, for example, sputtering. After that, the metal multilayer film including these films is patterned to form such layers as the source line 22f.

Finally, the entire substrate provided with the source line 22f is coated with, for example, a polyimide-based photosensitive resin film (approximately 2 μm in thickness) by spin coating or slit coating. After that, the coating film is pre-baked, exposed to light, developed, and post-baked to form the planarization film 23 having a contact hole.

As described above, the TFT layer 30 is successfully formed.

### Organic-EL-Element Layer Forming Step

On the planarization film 23 of the TFT layer 30 formed at the TFT-layer forming step, the first electrode 31, the edge cover 32, the organic EL layer 33 (including the hole injection layer 1, the hole transport layer 2, the light-emitting layer 3, the electron transport layer 4, and the electron injection layer 5), and the second electrode 34 are formed, using a known technique. Hence, the organic EL element layer 40 is formed.

### Sealing-Film Forming Step

First, on a substrate surface provided with the organic-EL-element layer 40 formed at the organic-EL-element-layer forming step, an inorganic insulating film such as, for example, a silicon nitride film, a silicon oxide film, or a silicon oxynitride film is deposited by the plasma CVD, using a mask. Hence, the first inorganic sealing film 41 is formed.

Then, on the substrate surface provided with the first inorganic sealing film 41, an organic resin material such as acrylic resin is deposited by, for example, inkjet printing. Hence, the organic sealing film 42 is formed.

After that, on the substrate surface provided with the organic sealing film 42, an inorganic insulating film such as, for example, a silicon nitride film, a silicon oxide film, or a silicon oxynitride film is deposited by the plasma CVD, using a mask, to form the second inorganic sealing film 43. Hence, the sealing film 45 is formed.

Finally, a protective sheet (not shown) is attached to the substrate surface provided with the sealing film 45. After that, a laser beam is emitted from toward the glass substrate of the resin substrate 10, and the glass substrate is removed from a lower surface of the resin substrate 10. To the lower surface of the resin substrate 10 from which the glass substrate is removed, a protective sheet (not shown) is attached.

As can be seen, the organic EL display device 50 of this embodiment is successfully produced.

As described above, in the organic EL display device 50 of this embodiment, the light-shielding film 12a has a peripheral end disposed outside a peripheral end of the semiconductor layer 14. Hence, the semiconductor layer 14 is not provided on a level difference created on a surface of the second base coat film 13 because of the peripheral end of the light-shielding film 12a. Hence, the semiconductor layer 14 is provided only on a flat portion of the surface of the second base coat film 13. Such a feature can reduce the risk that the semiconductor layer might be broken because of the level difference of the light-shielding film 12a provided to the semiconductor layer 14 toward the resin substrate 10.

In addition, in the organic EL display device 50 of this embodiment, the light-shielding film 12a is formed into a single piece among the plurality of subpixels P arranged side by side. Thanks to such a feature, for example, a predetermined voltage is applied to the light-shielding film 12a at one end to fix a potential of the light-shielding film 12a disposed over the entire display region D. Hence, the feature can reduce variations in the threshold values of the first TFT 9a to the seventh TFT 9g, and stabilize the characteristics of the TFTs.

### Second Embodiment

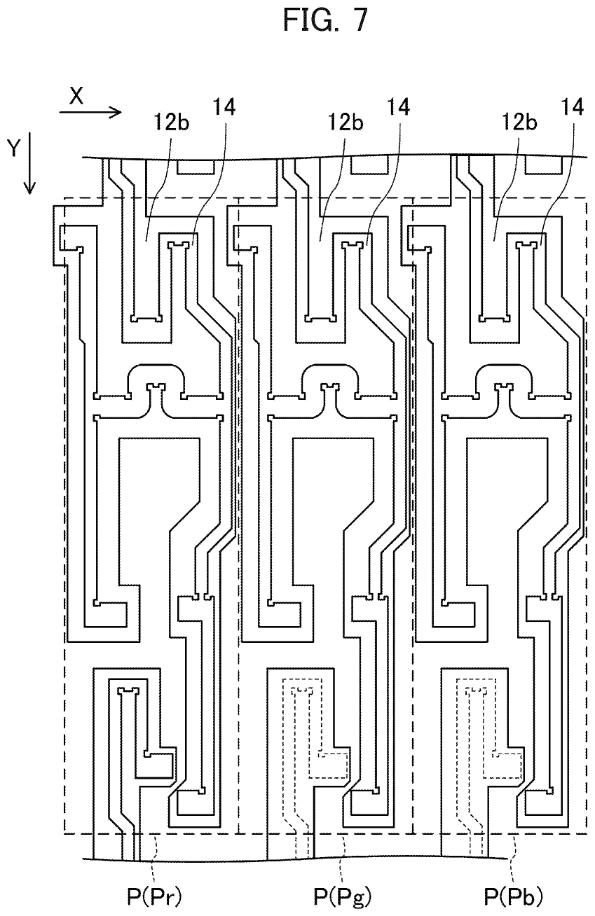

FIG. 7 illustrates a second embodiment of a display device according to the disclosure. Here, FIG. 7 is a plan view of an arrangement of a light-shielding film 12b and the semiconductor layer 14 included in a TFT layer of the organic EL display device of this embodiment. FIG. 7 corresponds to FIG. 5 in the first embodiment. Note that, in the embodiment below, like reference signs designate identical constituent features throughout FIGS. 1 to 6. These constituent features will not be elaborated upon here.

The first embodiment exemplifies the organic EL display device 50 in which the light-shielding film 12a is formed into a single piece among the plurality of subpixels P arranged side by side. Alternatively, this embodiment exemplifies an organic EL display device in which the light-shielding film 12b is provided separately for each of the subpixels P.

Similar to the organic EL display device 50 of the first embodiment, the organic EL display device of this embodiment includes, for example: the display region D shaped into a rectangle; and the picture-frame region F provided around the display region D.

Similar to the organic EL display device 50 of the first embodiment, the organic EL display device of this embodiment includes: the resin substrate 10; a TFT layer provided on the resin substrate 10; the organic EL element layer 40 provided on the TFT layer; and the sealing film 45 provided on the organic EL element layer 40.

The TFT layer included in the organic EL display device of this embodiment is solely provided with the light-shielding film 12b, instead of the light-shielding film 12a of the first embodiment, between the first base coat film 11 and the second base coat film 13. Otherwise, the TFT layer is substantially the same as the TFT layer 30 included in the organic EL display device 50 of the first embodiment.

The light-shielding film 12b is formed of a metal film such as, for example, a molybdenum film, a titanium film, or an aluminum film having a thickness of approximately 50 nm to 100 nm. The light-shielding film 12b is provided between the first basecoat film 11 and the second basecoat film 13. Here, as illustrated in FIG. 7, the light-shielding film 12b has a peripheral end disposed outside a peripheral end of the semiconductor layer 14. Hence, the semiconductor layer 14 is not provided on a level difference created on a surface of the second base coat film 13 because of the peripheral end of the light-shielding film 12b. Furthermore, as illustrated in FIG. 7, the light-shielding film 12b is provided separately and independently for each of the subpixels P.

Similar to the organic EL display device 50 of the first embodiment, the organic EL display device of this embodiment is flexible. The organic EL display device of this embodiment displays an image when, in each of the subpixels P, the light-emitting layer 3 of the organic EL layer 33 emits light as appropriate through the first TFT 9a, the second TFT 9b, the third TFT 9c, the fourth TFT 9d, the fifth TFT 9e, the sixth TFT 9f, and the seventh TFT 9g.

The organic EL display device of this embodiment can be produced by the method for producing the organic EL display device 50 of the first embodiment. At the TFT-layer forming step, the light-shielding film 12a is patterned into a different shape.

As described above, in the organic EL display device of this embodiment, the light-shielding film 12b has a peripheral end disposed outside a peripheral end of the semiconductor layer 14. Hence, the semiconductor layer 14 is not provided on a level difference created on a surface of the second base coat film 13 because of the peripheral end of the light-shielding film 12b. Hence, the semiconductor layer 14 is provided only on a flat portion of the surface of the second base coat film 13. Such a feature can reduce the risk that the semiconductor layer 14 might be broken because of the level difference of the light-shielding film 12b provided to the semiconductor layer 14 toward the resin substrate 10.

In addition, in the organic EL display device of this embodiment, the light-shielding film 12b is provided separately for each of the subpixels P. Hence, even if a crack opens in one of the light-shielding films 12b, such a feature can keep the crack from propagating into another light-shielding film 12b.

Furthermore, in the organic EL display device of this embodiment, the light-shielding film 12b is provided separately for each of the subpixels P. Such a feature makes it possible to disperse stress imposed on the light-shielding films 12b, and reduce warping of the resin substrate 10 and the entire organic EL display device including the resin substrate 10.

### Third Embodiment

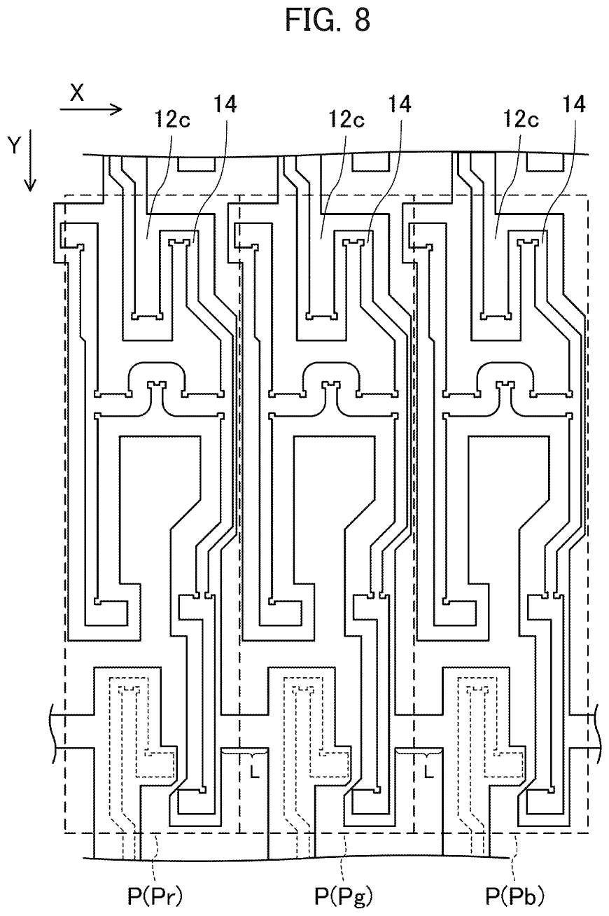

FIG. 8 illustrates a third embodiment of a display device according to the disclosure. Here, FIG. 8 is a plan view of an arrangement of a light-shielding film 12c and the semiconductor layer 14 included in a TFT layer of the organic EL display device of this embodiment. FIG. 8 corresponds to FIG. 5 in the first embodiment.

The first embodiment exemplifies the organic EL display device 50 in which the light-shielding f ilm 12a is formed into a single piece among the plurality of subpixels P arranged side by side. Alternatively, this embodiment exemplifies an organic EL display device in which a plurality of the light-shielding films 12c are coupled together with a coupling portion L.

Similar to the organic EL display device 50 of the first embodiment, the organic EL display device of this embodiment includes, for example: the display region D shaped into a rectangle; and the picture-frame region F provided around the display region D.

Similar to the organic EL display device 50 of the first embodiment, the organic EL display device of this embodiment includes: the resin substrate 10; a TFT layer provided on the resin substrate 10; the organic EL element layer 40 provided on the TFT layer; and the sealing film 45 provided on the organic EL element layer 40.

The TFT layer included in the organic EL display device of this embodiment is solely provided with the light-shielding film 12c, instead of the light-shielding film 12a of the first embodiment, between the first base coat film 11 and the second base coat film 13. Otherwise, the TFT layer is substantially the same as the TFT layer 30 included in the organic EL display device 50 of the first embodiment.

The light-shielding film 12c is formed of a metal film such as, for example, a molybdenum film, a titanium film, or an aluminum film having a thickness of approximately 50 nm to 100 nm. The light-shielding film 12c is provided between the first basecoat film 11 and the second basecoat film 13. Here, as illustrated in FIG. 8, the light-shielding film 12c has a peripheral end disposed outside a peripheral end of the semiconductor layer 14. Hence, the semiconductor layer 14 is not provided on a level difference created on a surface of the second base coat film 13 because of the peripheral end of the light-shielding film 12c. Furthermore, as illustrated in FIG. 8, a plurality of the light-shielding films 12c are coupled together, through the coupling portion L formed linearly, among the plurality of subpixels P arranged side by side in the X-direction in the drawing.

Similar to the organic EL display device 50 of the first embodiment, the organic EL display device of this embodiment is flexible. The organic EL display device of this embodiment displays an image when, in each of the subpixels P, the light-emitting layer 3 of the organic EL layer 33 emits light as appropriate through the first TFT 9a, the second TFT 9b, the third TFT 9c, the fourth TFT 9d, the fifth TFT 9e, the sixth TFT 9f, and the seventh TFT 9g.

The organic EL display device of this embodiment can be produced by the method for producing the organic EL display device 50 of the first embodiment. At the TFT-layer forming step, the light-shielding film 12a is patterned into a different shape.

As described above, in the organic EL display device of this embodiment, the light-shielding film 12c has a peripheral end disposed outside a peripheral end of the semiconductor layer 14. Hence, the semiconductor layer 14 is not provided on a level difference created on a surface of the second base coat film 13 because of the peripheral end of the light-shielding film 12c. Hence, the semiconductor layer 14 is provided only on a flat portion of the surface of the second base coat film 13. Such a feature can reduce the risk that the semiconductor layer 14 might be broken because of the level difference of the light-shielding film 12c provided to the semiconductor layer 14 toward the resin substrate 10.

In addition, in the organic EL display device of this embodiment, the light-shielding films 12c are coupled together, only through the coupling portion L, among the plurality of subpixels P arranged side by side. Hence, even if a crack opens in a light-shielding film 12c disposed for one subpixel P, such a feature can keep the crack from propagating into a light-shielding film 12c disposed for another subpixel P.

Furthermore, in the organic EL display device of this embodiment, the light-shielding films 12c are coupled together, only through the coupling portion L, among the plurality of subpixels P arranged side by side. Such a feature makes it possible to disperse stress imposed on the light-shielding films 12c, and reduce warping of the resin substrate 10 and the entire organic EL display device including the resin substrate 10.

Moreover, in the organic EL display device of this embodiment, the light-shielding films 12c are coupled together, only through the coupling portion L, among the plurality of subpixels P arranged side by side. Thanks to such a feature, for example, a predetermined voltage is applied to the light-shielding films 12c at one end to fix a potential of the light-shielding films 12c disposed over the entire display region D. Hence, the feature can reduce variations in the threshold values of the first TFT 9a to the seventh TFT 9g, and stabilize the characteristics of the TFTs.

### Other Embodiments

The above embodiments exemplify a case where each of the light-shielding films 12a, 12b, and 12c is patterned to have a peripheral end disposed outside a peripheral end of the semiconductor layer 14. Alternatively, the light-shielding films may be provided monolithically over the entire surface of the display region D.

Moreover, in each of the above embodiments, the exemplified organic EL layer has a multilayer structure including five layers such as a hole injection layer, a hole transport layer, a light-emitting layer, an electron transport layer, and an electron injection layer. Alternatively, the organic EL layer may have a multilayer structure including three layers such as, for example, a hole-injection-and-hole-transport layer, a light-emitting layer, and an electron-transport-and-electron-injection layer.

Moreover, in each of the above embodiments, the exemplified organic EL display device includes a first electrode as an anode and a second electrode as a cathode. The disclosure can also be applied to an organic EL display device whose multilayer structure of the organic EL layer is inverted, and the first electrode is a cathode and the second electrode is an anode.

In addition, in each of the embodiments, the organic EL display device is exemplified as a display device. The disclosure can be applied to a display device including a plurality of light-emitting elements driven by currents. For example, the disclosure can be applied to a display device including quantum-dot light-emitting diodes (QLEDs); that is, light-emitting elements including layers containing quantum dots.

### INDUSTRIAL APPLICABILITY

As described above, the disclosure is useful for a flexible display device.

1. A display device, comprising:
a resin substrate; and
a thin-film transistor layer provided on the resin substrate, and including a plurality of thin-film transistors arranged for each of a plurality of subpixels forming a display region,
each of the thin-film transistors having a semiconductor layer formed of a polysilicon film,
the plurality of thin-film transistors being electrically connected to one another through a conductor region of the semiconductor layer, and
the thin-film transistor layer including a light-shielding film provided to the semiconductor layer toward the resin substrate,
wherein the light-shielding film has a peripheral end disposed outside a peripheral end of the semiconductor layer including the conductor region.

2. The display device according to claim 1,
wherein the light-shielding film is provided separately for each of the subpixels.

3. The display device according to claim 1,
wherein the light-shielding film is formed into a single piece among the plurality of subpixels arranged side by side.

4. The display device according to claim 1,
wherein a plurality of the light-shielding films are coupled together, through a coupling portion formed linearly, among the plurality of subpixels arranged side by side.

5. A display device, comprising:
a resin substrate; and
a thin-film transistor layer provided on the resin substrate, and including a plurality of thin-film transistors arranged for each of a plurality of subpixels forming a display region,
each of the thin-film transistors having a semiconductor layer formed of a polysilicon film,
the plurality of thin-film transistors being electrically connected to one another through a conductor region of the semiconductor layer, and
the thin-film transistor layer including a light-shielding film provided to the semiconductor layer toward the resin substrate, wherein the light-shielding film is provided over an entire surface of the display region.

6. The display device according to claim 1,
wherein the thin-film transistor layer includes a first base coat film and a second base coat film sequentially stacked on top of another above the resin substrate, and
the light-shielding film is provided between the first base coat film and the second base coat film.

7. The display device according to claim 1,
wherein the light-shielding film is formed of a metal film.

8. The display device according to claim 1,
wherein the conductor region is doped with impurity ions.

9. The display device according to claim 1, further comprising:
a light-emitting-element layer provided on the thin-film transistor layer and including a plurality of light-emitting elements arranged to correspond to the plurality of subpixels; and
a sealing film provided on the light-emitting-element layer.

10. The display device according to claim 9,
wherein each of the light-emitting elements is an organic electroluminescence element.
